(19) United States
(12) Patent Application Publication
(10) Pub. No.: US 2026/0342334 A1
(43) Pub. Date: Oct. 29, 2026

(54) OUTPUT DRIVE CIRCUIT

(71) Applicant: DB HiTek Co., Ltd., Bucheon-si (KR)

(72) Inventors: Sangmok LEE, Bucheon-si (KR); Hyunsub JUNG, Bucheon-si (KR); Seunghyun KOO, Bucheon-si (KR); Jung-eun LEE, Bucheon-si (KR)

(73) Assignee: DB HiTek Co., Ltd., Bucheon-si (KR)

(21) Appl. No.: 19/538,667

(22) Filed: Feb. 12, 2026

(30) Foreign Application Priority Data
Apr. 25, 2025 (KR) 10-2025-0054641

(51) Int. Cl. H03K 17/687; H03K 19/0175

(52) U.S. Cl. CPC H03K 17/6872; H03K 19/017509

(57) ABSTRACT

An output drive circuit is provided. The output drive circuit comprises a control signal generation circuit configured to receive a data signal as input, and output a first control signal and a second control signal; a positive output drive circuit configured to receive the first control signal as input, and output a positive output signal; a negative output drive circuit configured to receive the second control signal as input, and output a negative output signal; a connection circuit connecting the positive output drive circuit and the negative output drive circuit; and an output terminal connected to the connection circuit.

### CROSS-REFERENCE TO RELATED APPLICATION

This application claims priority under 35 U.S.C §119 to Korean Patent Application No. 10-2025-0054641 filed on Apr. 25, 2025, in the Korean Intellectual Property Office, the entire contents of which are hereby incorporated by reference.

### BACKGROUND

### Technical Field

The disclosure relates to an output drive circuit, and more particularly, to an output drive circuit for outputting a low-voltage signal into a high-voltage signal.

### Description of the Related Art

The content set forth in this section merely provides background information on the present embodiments and does not constitute prior art.

In order to output low-voltage signals into high-voltage signals in the logic, output drive circuits are used. Switches such as transistors are used when outputting positive and negative voltage signals; however, there is a problem of requiring an on/off timing signal for each switch if multiple switches are used. When an on/off timing signal is applied to each of the multiple switches, high voltage can be caused and leakage may occur.

Therefore, it is necessary to output low-voltage signals into high-voltage signals, yet to reduce the number of switches used.

### BRIEF SUMMARY

It is an object of the present disclosure to provide an output drive circuit for outputting a control signal using a data signal, and outputting a low-voltage signal into a high-voltage signal using the control signal.

The objects of the present disclosure are not limited to the object mentioned above, and other objects and advantages of the present disclosure that have not been mentioned can be understood by the following description and will be understood more clearly by the embodiments of the present disclosure. Further, it will be readily appreciated that the objects and advantages of the present disclosure can be realized by the means set forth in the claims and combinations thereof.

According to some embodiments of the present disclosure, an output drive circuit comprising a control signal generation circuit configured to receive a data signal as input, and output a first control signal and a second control signal; a positive output drive circuit configured to receive the first control signal as input, and output a positive output signal; a negative output drive circuit configured to receive the second control signal as input, and output a negative output signal; a connection circuit connecting the positive output drive circuit and the negative output drive circuit; and an output terminal connected to the connection circuit, wherein when the data signal is at a first voltage level, the first control signal is at a second voltage level, and the second control signal is at the first voltage level, when the data signal is at a third voltage level, the first control signal is at the first voltage level, and the second control signal is at a fourth voltage level, when the data signal is at the first voltage level, the negative output signal at the fourth voltage level is output to the output terminal, and when the data signal is at the third voltage level, the positive output signal at the second voltage level is output to the output terminal.

According to some embodiments of the present disclosure, wherein the connection circuit comprises: a first transistor having one end connected to the positive output drive circuit and the other end connected to the output terminal; and a second transistor having one end connected to the output terminal and the other end connected to the negative output drive circuit.

According to some embodiments of the present disclosure, wherein the first voltage level is greater than the fourth voltage level, the third voltage level is greater than the first voltage level, and the second voltage level is greater than the third voltage level.

According to some embodiments of the present disclosure, wherein the control signal generation circuit comprises: a positive level shifter configured to receive the data signal as input, and output a first voltage signal; a negative level shifter configured to receive the data signal as input, and output a second voltage signal; and a pre-drive circuit configured to receive the first voltage signal and the second voltage signal as input, output the first control signal having the first voltage level to the second voltage level, and output the second control signal having the fourth voltage level to the first voltage level.

According to some embodiments of the present disclosure, the output drive circuit is further comprising: a HiZ generation circuit controlled by a HiZ control signal and connected to the positive output drive circuit, wherein when the HiZ control signal is at the second voltage level, the output terminal outputs one of the negative output signal and the positive output signal according to the data signal, and when the HiZ control signal is at the first voltage level, the output terminal enters a high-impedance state.

According to some embodiments of the present disclosure, wherein the control signal generation circuit comprises: a positive level shifter configured to receive the data signal as input and output a first voltage signal, and receive a first input signal as input and output a first input voltage signal; a negative level shifter configured to receive the data signal as input and output a second voltage signal, and receive the first input signal as input and output a second input voltage signal; and a pre-drive circuit configured to receive the first voltage signal, the second voltage signal, the first input voltage signal, and the second input voltage signal as input, and output the HiZ control signal, the first control signal, and the second control signal, and wherein the pre-drive circuit: outputs the first control signal having the first voltage level to the second voltage level, based on the first voltage signal, outputs the second control signal having the fourth voltage level to the first voltage level, based on the second voltage signal, and outputs the HiZ control signal having the first voltage level to the second voltage level, based on the first input voltage signal.

According to some embodiments of the present disclosure, wherein the HiZ generation circuit comprises a transistor having one end connected to the positive output drive circuit and the other end connected to a ground voltage and controlled by the HiZ control signal.

According to some embodiments of the present disclosure, wherein at a first node, the connection circuit and the positive output drive circuit are connected to each other, at a second node, the connection circuit and the negative output drive circuit are connected to each other, and the output drive circuit further comprising: a first additional circuit connected to the first node and a power supply at the second voltage level; and a second additional circuit connected to the second node and a power supply at the fourth voltage level.

According to some embodiments of the present disclosure, wherein the control signal generation circuit comprises: a positive level shifter configured to receive the data signal as input and output a first voltage signal, and receive a second input signal as input and output a third voltage signal; a negative level shifter configured to receive the data signal as input and output a second voltage signal, and receive the second input signal as input and output a fourth voltage signal; and a pre-drive circuit configured to receive the first voltage signal, the second voltage signal, the third voltage signal, and the fourth voltage signal as input, and output the first control signal, the second control signal, the third control signal, and the fourth control signal, and wherein the pre-drive circuit: outputs the first control signal having the first voltage level to the second voltage level, based on the first voltage signal, outputs the second control signal having the fourth voltage level to the first voltage level, based on the second voltage signal, outputs the third control signal having the first voltage level to the second voltage level, based on the third voltage signal, and outputs the fourth control signal having the fourth voltage level to the first voltage level, based on the fourth voltage signal.

According to some embodiments of the present disclosure, wherein the first additional circuit comprises a first additional transistor having one end connected to the power supply at the second voltage level and the other end connected to the first node, and the second additional circuit comprises a second additional transistor having one end connected to the second node and the other end connected to the power supply at the fourth voltage level.

According to some embodiments of the present disclosure, an output drive circuit comprising: a control signal generation circuit configured to receive a data signal as input, and output a first control signal and a second control signal; a positive output drive circuit configured to receive the first control signal as input, and output a positive output signal; a negative output drive circuit configured to receive the second control signal as input, and output a negative output signal; a connection circuit connecting the positive output drive circuit and the negative output drive circuit; and an output terminal connected to the connection circuit, wherein the connection circuit comprises: a first transistor having one end connected to the positive output drive circuit and the other end connected to the output terminal; and a second transistor having one end connected to the output terminal and the other end connected to the negative output drive circuit, and wherein the positive output drive circuit comprises: a third transistor having one end connected to a positive voltage and the other end connected to a first node, and controlled by the first control signal; and a fourth transistor having one end connected to the first node and the other end connected to a ground voltage, and controlled by the first control signal.

According to some embodiments of the present disclosure, wherein the negative output drive circuit comprises: a fifth transistor having one end connected to a second node and the other end connected to a negative voltage, and controlled by the second control signal; and a sixth transistor having one end connected to the second node and the other end connected to the ground voltage, and controlled by the second control signal.

According to some embodiments of the present disclosure, wherein when the data signal is at a first voltage level, the first control signal is at a second voltage level, and the second control signal is at the first voltage level, when the data signal is at a third voltage level, the first control signal is at the first voltage level, and the second control signal is at a fourth voltage level, when the data signal is at the first voltage level, the negative output signal at the fourth voltage level is output to the output terminal, and when the data signal is at the third voltage level, the positive output signal at the second voltage level is output to the output terminal.

According to some embodiments of the present disclosure, wherein the control signal generation circuit comprises: a positive level shifter configured to receive the data signal as input, and output a first voltage signal; a negative level shifter configured to receive the data signal as input, and output a second voltage signal; and a pre-drive circuit configured to receive the first voltage signal and the second voltage signal as input, output the first control signal having the first voltage level to the second voltage level, and output the second control signal having the fourth voltage level to the first voltage level.

According to some embodiments of the present disclosure, the output drive circuit further comprising: a HiZ generation circuit controlled by a HiZ control signal and connected to the positive output drive circuit, wherein when the HiZ control signal is at the second voltage level, the output terminal outputs one of the negative output signal and the positive output signal according to the data signal, and when the HiZ control signal is at the first voltage level, the output terminal enters a high-impedance state.

According to some embodiments of the present disclosure, wherein the HiZ generation circuit comprises a transistor having one end connected to the positive output drive circuit and the other end connected to the ground voltage and controlled by the HiZ control signal.

According to some embodiments of the present disclosure, wherein at the first node, the connection circuit and the positive output drive circuit are connected to each other, at a second node, the connection circuit and the negative output drive circuit are connected to each other, and the output drive circuit further comprising: a first additional circuit connected to the first node and a power supply at the second voltage level; and a second additional circuit connected to the second node and a power supply at the fourth voltage level.

According to some embodiments of the present disclosure, wherein the first additional circuit comprises a first additional transistor having one end connected to the power supply at the second voltage level and the other end connected to the first node, and the second additional circuit comprises a second additional transistor having one end connected to the second node and the other end connected to the power supply at the fourth voltage level.

According to some embodiments of the present disclosure, an output drive circuit comprising: a control signal generation circuit configured to receive a data signal as input, and output a first control signal and a second control signal; a positive output drive circuit configured to receive the first control signal as input, and output a positive output signal; a negative output drive circuit configured to receive the second control signal as input, and output a negative output signal; a connection circuit connecting the positive output drive circuit and the negative output drive circuit; an output terminal connected to the connection circuit; and a HiZ generation circuit controlled by a HiZ control signal and connected to the positive output drive circuit, wherein when the data signal is at a first voltage level, the first control signal is at a second voltage level, and the second control signal is at the first voltage level, when the data signal is at a third voltage level, the first control signal is at the first voltage level, and the second control signal is at a fourth voltage level, when the data signal is at the first voltage level, the negative output signal at the fourth voltage level is output to the output terminal, when the data signal is at the third voltage level, the positive output signal at the second voltage level is output to the output terminal, when the HiZ control signal is at the second voltage level, the output terminal outputs one of the negative output signal and the positive output signal according to the data signal, and when the HiZ control signal is at the first voltage level, the output terminal enters a high-impedance state.

According to some embodiments of the present disclosure, an output drive circuit comprising: control signal generation circuit configured to receive a data signal as input, and output a first control signal and a second control signal; a positive output drive circuit configured to receive the first control signal as input, and output a positive output signal; a negative output drive circuit configured to receive the second control signal as input, and output a negative output signal; a connection circuit connected to the positive output drive circuit via a first node and connected to the negative output drive circuit via a second node; an output terminal connected to the connection circuit; a first additional circuit connected to the first node and a power supply at a second voltage level; and a second additional circuit connected to the second node and a power supply at a fourth voltage level, wherein when the data signal is at a first voltage level, the first control signal is at the second voltage level, and the second control signal is at the first voltage level, when the data signal is at a third voltage level, the first control signal is at the first voltage level, and the second control signal is at the fourth voltage level, when the data signal is at the first voltage level, the negative output signal at the fourth voltage level is output to the output terminal, and when the data signal is at the third voltage level, the positive output signal at the second voltage level is output to the output terminal.

According to the output drive circuit of the present disclosure, a high-voltage signal can be output using a data signal, which is a low-voltage signal.

In addition to the foregoing description, specific effects of the present disclosure will be stated together while describing specific details for implementing the present disclosure below.

### BRIEF DESCRIPTION OF THE SEVERAL VIEWS OF THE DRAWINGS

FIG. 1 is a block diagram for describing an output drive circuit according to some embodiments of the present disclosure.

FIG. 2 is a diagram for describing signals of the output drive circuit according to some embodiments of the present disclosure.

FIG. 3 is a diagram for describing the control signal generation circuit of FIG. 1.

FIG. 4 is a diagram for describing the positive output drive circuit, the negative output drive circuit, and the connection circuit of FIG. 1.

FIG. 5 is a block diagram for describing an output drive circuit according to some embodiments of the present disclosure.

FIG. 6 is a diagram for describing the control signal generation circuit of FIG. 5.

FIG. 7 is a diagram for describing the positive output drive circuit, the negative output drive circuit, and the connection circuit of FIG. 5.

FIG. 8 is a block diagram for describing an output drive circuit according to some embodiments of the present disclosure.

FIG. 9 is a block diagram for describing an output drive circuit according to some embodiments of the present disclosure.

FIG. 10 is a diagram for describing the control signal generation circuit of FIG. 8.

FIG. 11 is a diagram for describing the positive output drive circuit, the negative output drive circuit, and the connection circuit of FIG. 8.

### DETAILED DESCRIPTION

The terms or words used in the disclosure and the claims should not be construed as limited to their ordinary or lexical meanings. They should be construed as the meaning and concept in line with the technical idea of the disclosure based on the principle that the inventor can define the concept of terms or words in order to describe his/her own inventive concept in the best possible way. Further, since the embodiment described herein and the configurations illustrated in the drawings are merely one embodiment in which the disclosure is realized and do not represent all the technical ideas of the disclosure, it should be understood that there may be various equivalents, variations, and applicable examples that can replace them at the time of filing this application.

Although terms such as first, second, A, B, etc., used in the description and the claims may be used to describe various components, the components should not be limited by these terms. These terms are only used to differentiate one component from another. For example, a first component may be referred to as a second component, and similarly, a second component may be referred to as a first component, without departing from the scope of the disclosure. The term ‘and/or’ includes a combination of a plurality of related listed items or any item of the plurality of related listed items.

As used herein, the term "connected" is intended to have the broadest possible meaning. Specifically, the phrase "A is connected to B" encompasses both a direct connection—where no intervening components or elements are present—and an indirect connection, where one or more intermediate components or elements exist between A and B. In other words, "A is connected to B" includes both direct physical or electrical coupling and indirect coupling through one or more intervening components. Unless explicitly stated otherwise, these terms do not require direct physical or electrical contact. The terms "coupled" and "in contact" should be interpreted in the same manner.

The terms used in the description and the claims are merely used to describe particular embodiments and are not intended to limit the disclosure. Singular forms are intended to include plural forms unless the context clearly indicates otherwise. In the application, terms such as “comprise,” “comprise,” “have,” etc., should be understood as not precluding the possibility of existence or addition of features, numbers, steps, operations, components, parts, or combinations thereof described herein.

Unless being defined otherwise, all terms used herein, including technical or scientific terms, have the same meaning as commonly understood by those skilled in the art to which the disclosure pertains.

Terms such as those defined in commonly used dictionaries should be construed as having a meaning consistent with the meaning in the context of the relevant art, and are not to be construed in an ideal or excessively formal sense unless explicitly defined in the application.

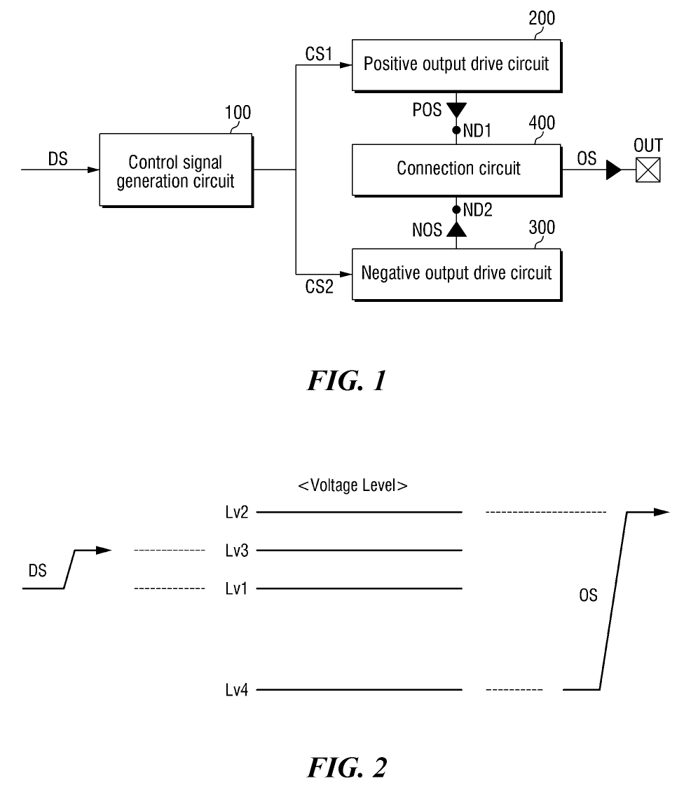

Hereinafter, an output drive circuit according to some embodiments of the present disclosure will be described with reference to FIGS. 1, 2, 3, and 4.

FIG. 1 is a block diagram for describing an output drive circuit according to some embodiments of the present disclosure.

Referring to FIG. 1, the output drive circuit may include a control signal generation circuit 100, a positive output drive circuit 200, a negative output drive circuit 300, and a connection circuit 400.

The control signal generation circuit 100 can receive a data signal DS as input, and output a first control signal CS1 and a second control signal CS2. The positive output drive circuit 200 can receive the first control signal CS1 as input, and output a positive output signal POS. The negative output drive circuit 300 can receive the second control signal CS2 as input, and output a negative output signal NOS.

The connection circuit 400 can connect the positive output drive circuit 200 and the negative output drive circuit 300. For example, the positive output drive circuit 200 may be connected to the connection circuit 400 via a first node ND1, and the negative output drive circuit 300 may be connected to the connection circuit 400 via a second node ND2.

The output terminal OUT of the output drive circuit can be connected to the connection circuit 400. The output signal OS of the connection circuit 400 can be output to the output terminal OUT.

FIG. 2 is a diagram for describing signals of the output drive circuit according to some embodiments of the present disclosure.

Referring to FIGS. 1 and 2, the data signal DS may be a signal having a voltage level in the range of a first voltage level Lv1 to a third voltage level Lv3. The output signal OS output to the output terminal OUT of the output drive circuit may be a signal having a voltage level in the range of a fourth voltage level Lv4 to a second voltage level Lv2. The fourth voltage level Lv4 is lower than the first voltage level Lv1, and the second voltage level Lv2 is higher than the first voltage level Lv1 and the third voltage level Lv3. The magnitude (e.g., absolute value) of the fourth voltage level Lv4 is greater than the magnitude of the third voltage level Lv3. The magnitude of the second voltage level Lv2 is greater than the magnitude of the third voltage level Lv3.

The data signal DS with a low voltage level can be output as the output signal OS with a high voltage level by way of the output drive circuit according to an embodiment of the present disclosure.

For example, the first voltage level Lv1 may be 0 V (volt). The fourth voltage level Lv4 may be a negative voltage. The third voltage level Lv3 and the second voltage level Lv2 may be positive voltages.

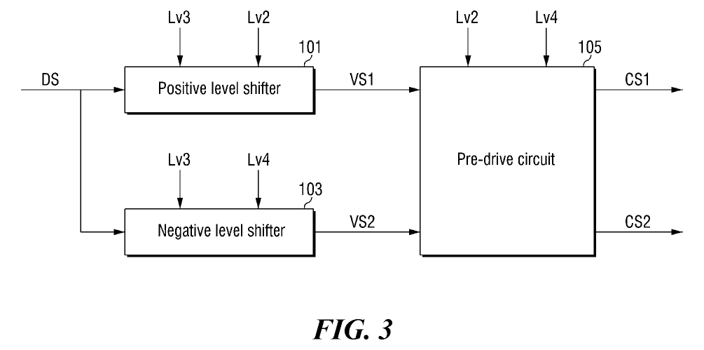

FIG. 3 is a diagram for describing the control signal generation circuit of FIG. 1.

Referring to FIGS. 1, 2, and 3, the control signal generation circuit 100 may include a positive level shifter 101, a negative level shifter 103, and a pre-drive circuit 105.

The positive level shifter 101 can receive the data signal DS as input, and output a first voltage signal VS1. The positive level shifter 101 can receive the data signal DS from inside the chip as input, and can output the first voltage signal VS1, which is a positive voltage signal higher than the voltage level of the data signal DS, by using a power supply at the second voltage level Lv2 and a power supply at the third voltage level Lv3. The first voltage signal VS1 may be a signal having a voltage level in the range of the first voltage level Lv1 to the second voltage level Lv2.

The negative level shifter 103 can receive the data signal DS as input, and output a second voltage signal VS2. The negative level shifter 103 can receive the data signal DS as input, and can output the second voltage signal VS2, which is a negative voltage signal with a magnitude greater than that of the voltage level of the data signal DS, by using the power supply at the third voltage level Lv3 and a power supply at the fourth voltage level Lv4. The second voltage signal VS2 may be a signal having a voltage level in the range of the first voltage level Lv1 to the fourth voltage level Lv4.

The pre-drive circuit 105 can receive the first voltage signal VS1 and the second voltage signal VS2 as input, and output the first control signal CS1 and the second control signal CS2. The pre-drive circuit 105 can output the first control signal CS1 and the second control signal CS2 by using the power supply at the second voltage level Lv2 and the power supply at the fourth voltage level Lv4.

The pre-drive circuit 105 can output the first control signal CS1, which is a positive voltage signal. The first control signal CS1 may be a signal having a voltage level ranging from the first voltage level Lv1 to the second voltage level Lv2. The pre-drive circuit 105 can output the second control signal CS2, which is a negative voltage signal. The second control signal CS2 may be a signal having a voltage level ranging from the first voltage level Lv1 to the fourth voltage level Lv4.

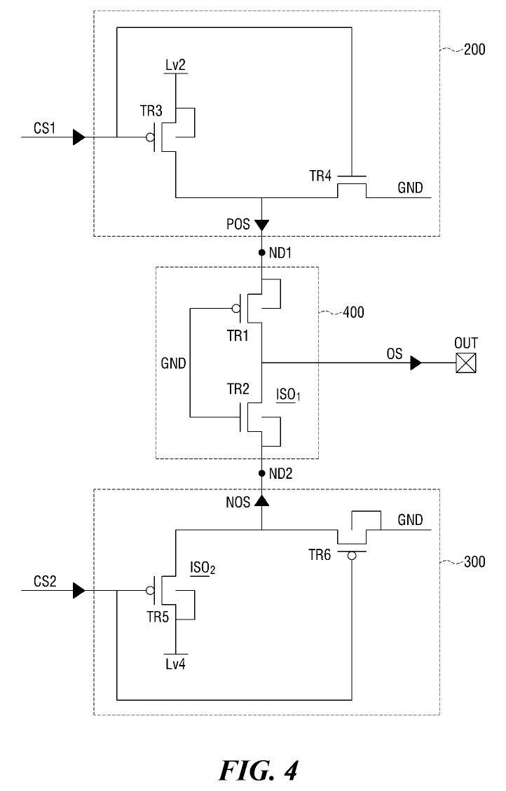

FIG. 4 is a diagram for describing the positive output drive circuit, the negative output drive circuit, and the connection circuit of FIG. 1.

Referring to FIGS. 1, 2, 3, and 4, the positive output drive circuit 200 can receive the first control signal CS1 as input, and output the positive output signal POS to the first node ND1. The negative output drive circuit 300 can receive the second control signal CS2 as input, and output the negative output signal NOS to the second node ND2. The connection circuit 400 can receive the positive output signal POS and the negative output signal NOS as input, and output the output signal OS to the output terminal OUT.

The connection circuit 400 may include a first transistor TR1 and a second transistor TR2. One end of the first transistor TR1 can be connected to the first node ND1 and thus to the positive output drive circuit 200, and the other end can be connected to the output terminal OUT. The gate of the first transistor TR1 can be connected to the ground voltage GND.

One end of the first transistor TR1 can be connected to the first node ND1 via a first bulk region. The first bulk region may be a partial region formed within the substrate in which the first transistor TR1 is disposed. The first transistor TR1 may be, for example, a PMOS transistor. If the first transistor TR1 is a PMOS transistor, the first bulk region may be an n-type well.

One end of the second transistor TR2 can be connected to the output terminal OUT, and the other end can be connected to the second node ND2 and thus to the negative output drive circuit 300. The gate of the second transistor TR2 can be connected to the ground voltage GND. The other end of the second transistor TR2 can be connected to the second node ND2 via a second bulk region ISO1. The second bulk region ISO1 may be a partial region formed within the substrate in which the second transistor TR2 is disposed. The second transistor TR2 may be, for example, an NMOS transistor. If the second transistor TR2 is an NMOS transistor, the second bulk region ISO1 may be a p-type well.

The positive output drive circuit 200 may include a third transistor TR3 and a fourth transistor TR4.

One end of the third transistor TR3 can be connected to the power supply at the second voltage level Lv2, and the other end can be connected to the first node ND1. The first control signal CS1 can be input to the gate of the third transistor TR3. One end of the third transistor TR3 can be connected to the power supply at the second voltage level Lv2 via a third bulk region. The third bulk region may be a partial region formed within the substrate in which the third transistor TR3 is disposed. The third transistor TR3 may be, for example, a PMOS transistor. If the third transistor TR3 is a PMOS transistor, the third bulk region may be an n-type well.

One end of the fourth transistor TR4 can be connected to the first node ND1, and the other end can be connected to the ground voltage GND. The first control signal CS1 can be input to the gate of the fourth transistor TR4. The fourth transistor TR4 may be, for example, an NMOS transistor.

The negative output drive circuit 300 may include a fifth transistor TR5 and a sixth transistor TR6.

One end of the fifth transistor TR5 can be connected to the second node ND2, and the other end can be connected to the power supply at the fourth voltage level Lv4. The second control signal CS2 can be input to the gate of the fifth transistor TR5. The other end of the fifth transistor TR5 can be connected to the power supply at the fourth voltage level Lv4 via a fifth bulk region ISO2. The fifth bulk region ISO2 may be a partial region formed within the substrate in which the fifth transistor TR5 is disposed. The fifth transistor TR5 may be, for example, an NMOS transistor. If the fifth transistor TR5 is an NMOS transistor, the fifth bulk region ISO2 may be a p-type well.

The second bulk region ISO1 and the fifth bulk region ISO2 may be different regions within the substrate and may be isolated from each other.

One end of the sixth transistor TR6 can be connected to the second node ND2, and the other end can be connected to the ground voltage GND. The second control signal CS2 can be input to the gate of the sixth transistor TR6. The other end of the sixth transistor TR6 can be connected to the ground voltage GND via a sixth bulk region. The sixth bulk region may be a partial region formed within the substrate in which the sixth transistor TR6 is disposed. The sixth transistor TR6 may be, for example, a PMOS transistor. If the sixth transistor TR6 is a PMOS transistor, the sixth bulk region may be an n-type well.

When the data signal DS is at the first voltage level Lv1 (e.g., 0 V), the first control signal CS1 can take on the second voltage level Lv2, which is a positive voltage, and the second control signal CS2 can take on the first voltage level Lv1.

The third transistor TR3, in which the first control signal CS1 at the second voltage level Lv2 has been input to its gate, can be turned off, and the fourth transistor TR4 can be turned on, allowing the ground voltage GND (e.g., 0 V) to be applied to the first node ND1. That is, the positive output signal POS can be 0 V. In this case, even if a negative voltage (e.g., a voltage signal at the fourth voltage level Lv4) is output to the output terminal OUT, leakage can be prevented since the first transistor TR1 will be in the turned-off state. In addition, a voltage difference between the first voltage level Lv1 and the fourth voltage level Lv4 can be caused in the first transistor TR1 between the first node ND1 and the output terminal OUT, preventing a high voltage from being applied between one end and the other end of the first transistor TR1, and moreover, safely blocking the leakage path from the power supply at the second voltage level Lv2 to the output terminal OUT.

The fifth transistor TR5, in which the second control signal CS2 at the first voltage level Lv1 has been input to its gate, can be turned on, and the sixth transistor TR6 can be turned off, allowing a voltage at the fourth voltage level Lv4 to be applied to the second node ND2. That is, the negative output signal NOS can be at the fourth voltage level Lv4. At this time, the second transistor TR2 can be turned on, and the negative output signal NOS at the fourth voltage level Lv4 can be output as the output signal OS to the output terminal OUT. Due to the application of the ground voltage GND, which is a higher voltage than the fourth voltage level Lv4, the second bulk region ISO1 can take on a negative voltage (e.g., the fourth voltage level Lv4).

Therefore, when the data signal DS is at the first voltage level Lv1, a negative output signal NOS at the fourth voltage level Lv4 can be output to the output terminal OUT.

When the data signal DS is at the third voltage level Lv3 (e.g., a power supply voltage VDD), the first control signal CS1 can take on the first voltage level Lv1 (e.g., 0 V), and the second control signal CS2 can take on the fourth voltage level Lv4, which is a negative voltage.

The third transistor TR3, in which the first control signal CS1 at the first voltage level Lv1 has been input to its gate, can be turned on, and the fourth transistor TR4 can be turned off, allowing the second voltage level Lv2 to be applied to the first node ND1. That is, the positive output signal POS can be at the second voltage level Lv2, which is a positive voltage. The first transistor TR1 can be turned on, and therefore, the second voltage level Lv2, which is a positive voltage, can be output as the output signal OS to the output terminal OUT.

The fifth transistor TR5, in which the second control signal CS2 at the fourth voltage level Lv4 has been input to its gate, can be turned off, and the sixth transistor TR6 can be turned on, allowing the ground voltage GND (e.g., 0 V) to be applied to the second node. In this case, even if a positive voltage (e.g., a voltage signal at the second voltage level Lv2) is output to the output terminal OUT, leakage can be prevented since the second transistor TR2 will be in the turned-off state. In addition, a voltage difference between the first voltage level Lv1 and the second voltage level Lv2 can be caused in the second transistor TR2 between the second node ND2 and the output terminal OUT, preventing a high voltage from being applied between one end and the other end of the second transistor TR2, and moreover, safely blocking the leakage path from the output terminal OUT to the power supply at the fourth voltage level Lv4.

Therefore, when the data signal DS is at the third voltage level Lv3, a positive output signal POS at the second voltage level Lv2 can be output to the output terminal OUT.

In conclusion, the data signal DS having a low voltage level ranging from the first voltage level Lv1 to the third voltage level Lv3 can be output as the output signal OS at a high voltage level having a voltage range from the fourth voltage level Lv4 to the second voltage level Lv2 via the output drive circuit in accordance with some embodiments of the present disclosure.

Furthermore, according to the output drive circuit in accordance with some embodiments of the present disclosure, by generating the first control signal CS1 and the second control signal CS2 using the data signal DS and outputting the output signal OS having a high voltage level range, the number of switches (e.g., transistors) used in the output drive circuit can be reduced, and additional control signals can be unnecessary.

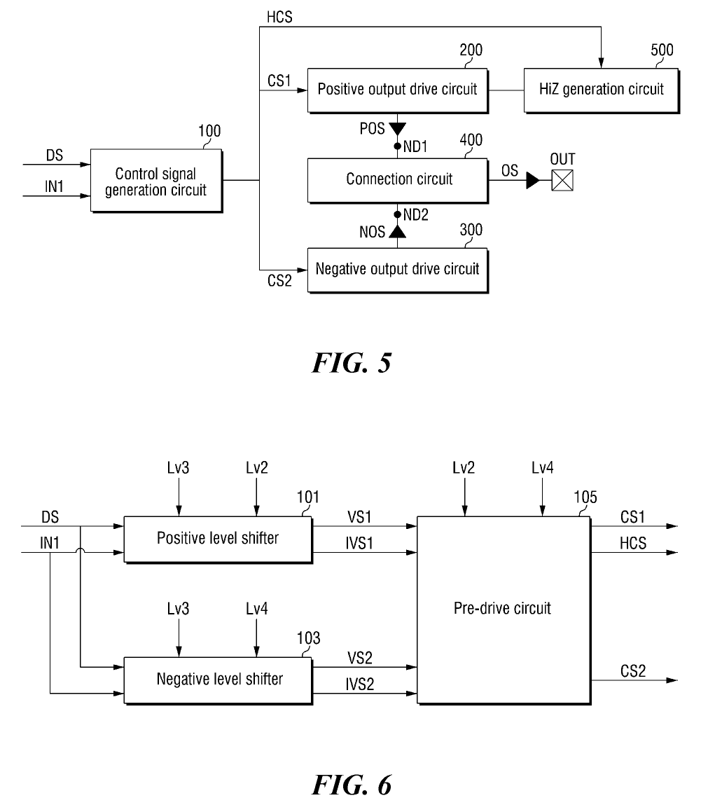

In the following, an output drive circuit according to some embodiments of the present disclosure will be described with reference to FIGS. 5, 6, and 7. For the clarity of description, any parts that overlap with what has been described above will be simplified or omitted.

FIG. 5 is a block diagram for describing an output drive circuit according to some embodiments of the present disclosure.

Referring to FIG. 5, the output drive circuit may further include a HiZ generation circuit 500.

The HiZ generation circuit 500 can be connected to the positive output drive circuit 200. The HiZ generation circuit 500 can be controlled by a HiZ control signal HCS. The HiZ generation circuit 500 can set the output terminal OUT to a high-impedance state.

FIG. 6 is a diagram for describing the control signal generation circuit of FIG. 5.

Referring to FIGS. 5 and 6, the control signal generation circuit 100 can receive a data signal DS and a first input signal IN1 as input, and output a first control signal CS1, a second control signal CS2, and a HiZ control signal HCS. The first input signal IN1 may be an input signal provided from another circuit inside the chip to which the data signal DS is provided.

The positive level shifter 101 can receive the first input signal IN1 as input, and output a first input voltage signal IVS1. The positive level shifter 101 can receive the first input signal IN1 as input, and output the first input voltage signal IVS1, which is a positive voltage signal higher than the voltage level of the first input signal IN1, by using the power supply at the second voltage level Lv2 and the power supply at the third voltage level Lv3. The first input voltage signal IVS1 may be a signal having a voltage level in the range of the first voltage level Lv1 to the second voltage level Lv2.

The negative level shifter 103 can receive the first input signal IN1 as input, and output a second input voltage signal IVS2. The negative level shifter 103 can receive the first input signal IN1 as input, and output the second input voltage signal IVS2, which is a negative voltage signal with a magnitude greater than that of the voltage level of the first input signal IN1, by using the power supply at the third voltage level Lv3 and the power supply at the fourth voltage level Lv4. The second input voltage signal IVS2 may be a signal having a voltage level in the range of the first voltage level Lv1 to the fourth voltage level Lv4.

The pre-drive circuit 105 can receive the first input voltage signal IVS1 and the second input voltage signal IVS2, and output the HiZ control signal HCS. The pre-drive circuit 105 can output the HiZ control signal HCS by using the power supply at the second voltage level Lv2 and the power supply at the fourth voltage level Lv4. The pre-drive circuit 105 can output the HiZ control signal HCS, which is a positive voltage signal. The HiZ control signal HCS may be a signal having a voltage level ranging from the first voltage level Lv1 to the second voltage level Lv2.

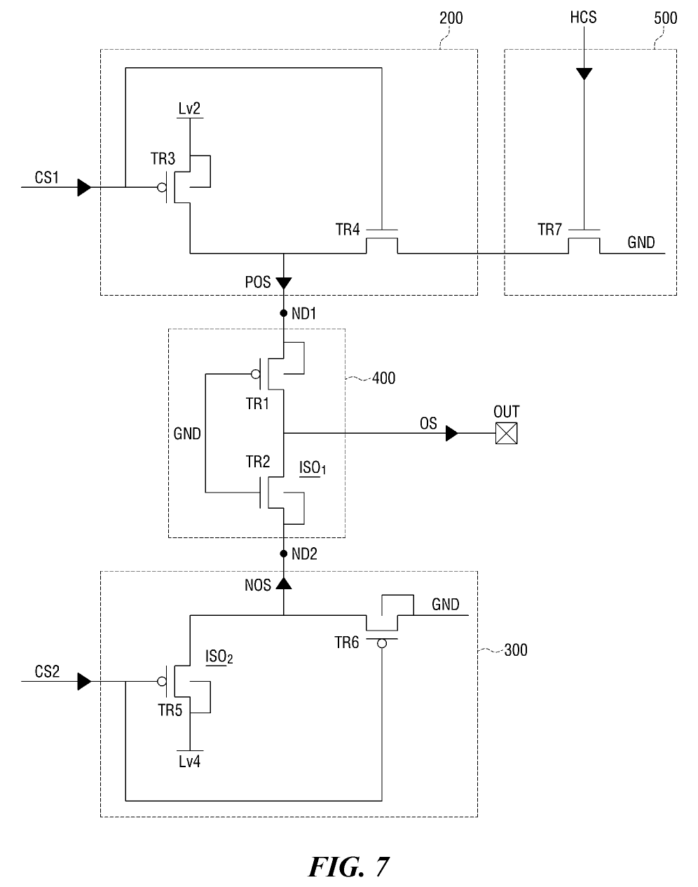

FIG. 7 is a diagram for describing the positive output drive circuit, the negative output drive circuit, and the connection circuit of FIG. 5.

Referring to FIGS. 5, 6, and 7, the HiZ generation circuit 500 can be connected to the positive output drive circuit 200.

The HiZ generation circuit 500 can be connected to the other end of the fourth transistor TR4 of the positive output drive circuit 200. If the HiZ generation circuit 500 is connected to the positive output drive circuit 200, the other end of the fourth transistor TR4 can be connected to the HiZ generation circuit 500 instead of the ground voltage GND.

The HiZ generation circuit 500 may include a seventh transistor TR7.

One end of the seventh transistor TR7 can be connected to the other end of the fourth transistor TR4, and the other end of the seventh transistor TR7 can be connected to the ground voltage GND. The HiZ control signal HCS can be input to the gate of the seventh transistor TR7.

When the first input signal IN1 is at the third voltage level Lv3 (e.g., the power supply voltage VDD), the HiZ control signal HCS can take on the second voltage level Lv2, which is a positive voltage. The seventh transistor is turned on by the HiZ control signal HCS at the second voltage level Lv2, and the ground voltage GND is input to the other end of the fourth transistor TR4. In this case, as described with reference to FIGS. 1 - 4, the output drive circuit operates, and an output signal OS having a voltage range from the fourth voltage level Lv4 to the second voltage level Lv2 can be output to the output terminal OUT.

That is, when the HiZ control signal HCS is at the second voltage level Lv2, one of a negative output signal NOS or a positive output signal POS can be output as the output signal OS to the output terminal OUT according to the data signal DS.

When the first input signal IN1 is at the first voltage level Lv1 (e.g., 0 V), the HiZ control signal HCS also takes on the first voltage level Lv1, and the seventh transistor TR7 is turned off. Further, when the first input signal IN1 is at the first voltage level Lv1 (e.g., 0 V), the first control signal CS1 takes on the second voltage level Lv2, which is a positive voltage, and the third transistor TR3 is turned off. As the seventh transistor TR7 is turned off, the path from the first node ND1 to the ground voltage GND is blocked, and as the third transistor TR3 is turned off, the path from the first node ND1 to the power supply at the second voltage level Lv2 is blocked.

In addition, the second control signal CS2 takes on the fourth voltage level, which is a negative voltage, and thus, the fifth transistor TR5 is turned off, and the sixth transistor TR6 is turned on, applying the ground voltage GND to the second node ND2. The second transistor TR2 is turned off, and the path from the second node ND2 to the ground voltage GND and the path from the second node ND2 to the power supply at the fourth voltage level Lv4 are blocked.

Ultimately, when the HiZ control signal HCS is at the first voltage level Lv1, the output terminal OUT enters a high-impedance state, which is a HiZ state.

The output drive circuit according to some embodiments of the present disclosure can not only output an output signal OS having a high voltage level range by using the data signal DS, but also set the output drive circuit to a HiZ state by using the first input signal IN1.

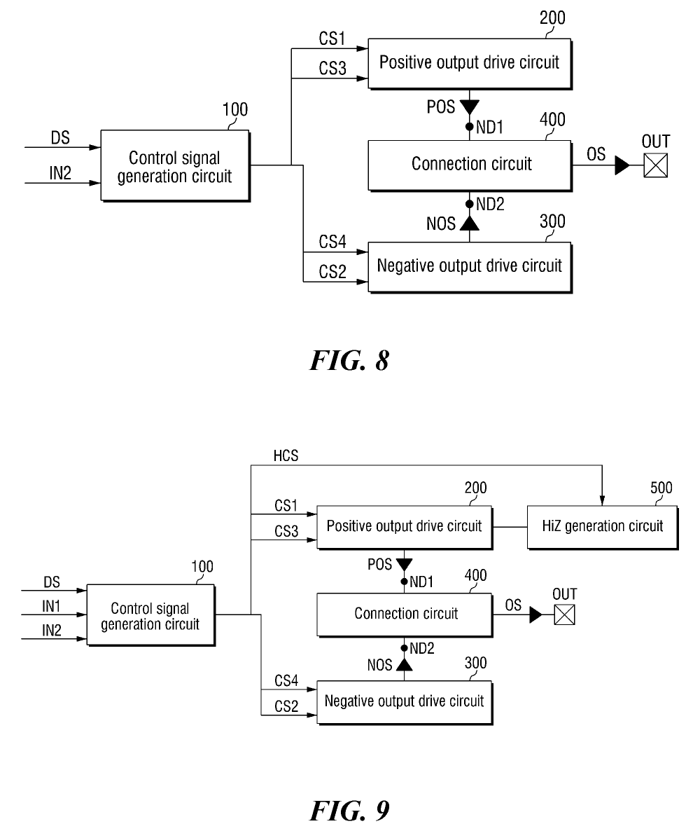

In the following, an output drive circuit according to some embodiments of the present disclosure will be described with reference to FIGS. 8, 9, 10, and 11. For the clarity of description, any parts that overlap with what has been described above will be simplified or omitted.

FIG. 8 is a block diagram for describing an output drive circuit according to some embodiments of the present disclosure. FIG. 9 is a block diagram for describing an output drive circuit according to some embodiments of the present disclosure.

Referring to FIGS. 8 and 9, the output drive circuit can receive not only the data signal DS but also a second input signal IN2 as input. In the embodiment where the output drive circuit further includes a HiZ generation circuit 500 as in FIG. 9, the output drive circuit can receive not only the data signal DS but also the first input signal IN1 and the second input signal IN2 as input.

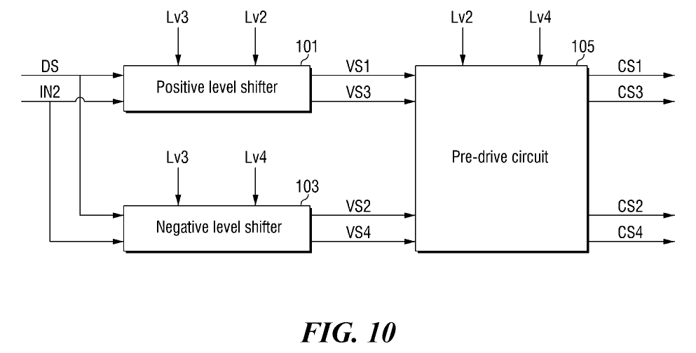

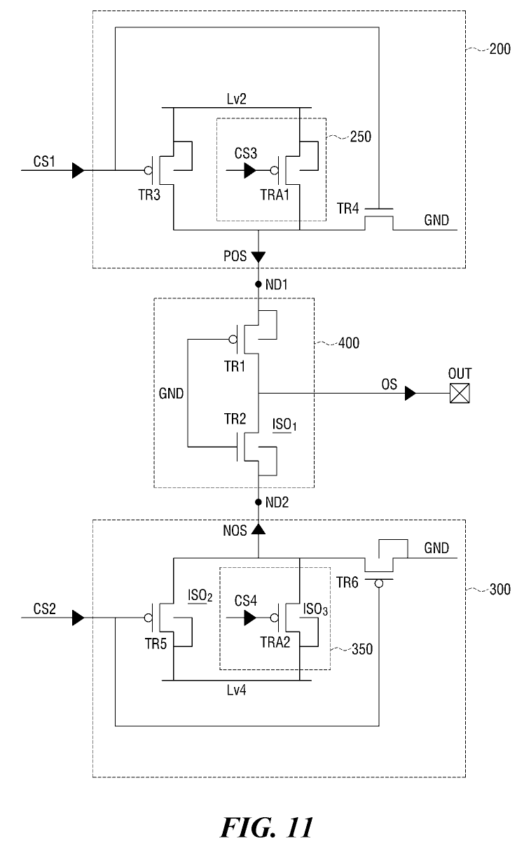

In the following, a description will be provided focusing on the circuit of FIG. 8. The descriptions for FIGS. 10 and 11 below can also be applied to the circuit diagram of FIG. 9.

FIG. 10 is a diagram for describing the control signal generation circuit of FIG. 8.

Referring to FIGS. 8 and 10, the control signal generation circuit 100 can receive the data signal DS and the second input signal IN2 as input, and output a first control signal CS1, a second control signal CS2, a third control signal CS3, and a fourth control signal CS4.

The positive level shifter 101 can receive the second input signal IN2 as input, and output a third voltage signal VS3. The positive level shifter 101 can receive the second input signal IN2 as input, and output the third voltage signal VS3, which is a positive voltage signal higher than the voltage level of the second input signal IN2, by using the power supply at the second voltage level Lv2 and the power supply at the third voltage level Lv3. The third voltage signal VS3 may be a signal having a voltage level in the range of the first voltage level Lv1 to the second voltage level Lv2.

The negative level shifter 103 can receive the second input signal IN2 as input, and output a fourth voltage signal VS4. The negative level shifter 103 can receive the second input signal IN2 as input, and output the fourth voltage signal VS4, which is a negative voltage signal with a magnitude greater than that of the voltage level of the second input signal IN2, by using the power supply at the third voltage level Lv3 and the power supply at the fourth voltage level Lv4. The fourth voltage signal VS4 may be a signal having a voltage level in the range of the first voltage level Lv1 to the fourth voltage level Lv4.

The pre-drive circuit 105 can receive the third voltage signal VS3 and the fourth voltage signal VS4 as input, and output the third control signal CS3 and the fourth control signal CS4. The pre-drive circuit 105 can output the third control signal CS3 and the fourth control signal CS4 by using the power supply at the second voltage level Lv2 and the power supply at the fourth voltage level Lv4.

The pre-drive circuit 105 can output the third control signal CS3, which is a positive voltage signal. The third control signal CS3 may be a signal having a voltage level ranging from the first voltage level Lv1 to the second voltage level Lv2. The pre-drive circuit 105 can output the fourth control signal CS4, which is a negative voltage signal. The fourth control signal CS4 may be a signal having a voltage level ranging from the first voltage level Lv1 to the fourth voltage level Lv4.

When the second input signal IN2 is at the first voltage level Lv1, the third control signal CS3 can be generated at the second voltage level Lv2, and the fourth control signal CS4 can be generated at the fourth voltage level Lv4.

When the second input signal IN2 is at the third voltage level Lv3, the third control signal CS3 can be determined according to the data signal DS in the same way as the first control signal CS1, and the fourth control signal CS4 can be determined according to the data signal DS in the same way as the second control signal CS2.

The second input signal IN2 may be an input signal provided from another circuit inside the chip to which the data signal DS is provided.

FIG. 11 is a diagram for describing the positive output drive circuit, the negative output drive circuit, and the connection circuit of FIG. 8.

Referring to FIGS. 8, 10, and 11, the positive output drive circuit 200 may further include a first additional circuit 250, and the negative output drive circuit 300 may further include a second additional circuit 350.

The first additional circuit 250 can be connected to the first node ND1 and the power supply at the second voltage level Lv2. The first additional circuit 250 may include a first additional transistor TRA1.

One end of the first additional transistor TRA1 can be connected to the power supply at the second voltage level Lv2, and the other end can be connected to the first node ND1. The third control signal CS3 can be input to the gate of the first additional transistor TRA1. One end of the first additional transistor TRA1 can be connected to the power supply at the second voltage level Lv2 via the third bulk region. The third bulk region may be a partial region formed within the substrate in which the first additional transistor TRA1 is disposed. The first additional transistor TRA1 may be, for example, a PMOS transistor. If the first additional transistor TRA1 is a PMOS transistor, the third bulk region may be an n-type well.

The second additional circuit 350 can be connected to the second node ND2 and the power supply at the fourth voltage level Lv4. The second additional circuit 350 may include a second additional transistor TRA2.

One end of the second additional transistor TRA2 can be connected to the second node ND2, and the other end can be connected to the power supply at the fourth voltage level Lv4. The fourth control signal CS4 can be input to the gate of the second additional transistor TRA2. The other end of the second additional transistor TRA2 can be connected to the power supply at the fourth voltage level Lv4 via a sixth bulk region ISO3. The sixth bulk region ISO3 may be a partial region formed within the substrate in which the second additional transistor TRA2 is disposed. The second additional transistor TRA2 may be, for example, an NMOS transistor. If the second additional transistor TRA2 is an NMOS transistor, the sixth bulk region ISO3 may be a p-type well.

The second bulk region ISO1, the fifth bulk region ISO2, and the sixth bulk region ISO3 may be different regions within the substrate and may be isolated from each other.

When the second input signal IN2 is at the first voltage level Lv1 (e.g., 0 V), the third control signal CS3 can take on the second voltage level Lv2, which is a positive voltage, and the first additional transistor TRA1 can be turned off. Further, the fourth control signal CS4 can take on the fourth voltage level Lv4, and the second additional transistor TRA2 can be turned off. In this case, the output signal OS can be output as described with reference to FIGS. 1 - 4.

When the second input signal IN2 is at the third voltage level Lv3 (e.g., the power supply voltage VDD), the first additional transistor TRA1 can operate the same as the third transistor TR3, and the second additional transistor TRA2 can operate the same as the fifth transistor TR5. In this case, the third control signal CS3 can be determined according to the data signal DS in the same way as the first control signal CS1, and the fourth control signal CS4 can be determined according to the data signal DS in the same way as the second control signal CS2.

When the positive output signal POS is output as the output signal OS, the first additional transistor TRA1 and the third transistor TR3 can be turned on, the first control signal CS1 and the third control signal CS3 can be in the same phase, and a positive voltage greater than the second voltage level Lv2 can be output to the output terminal OUT. At this time, the negative output drive circuit 300 can be in a disabled state due to the turn-off of the second transistor TR2.

When the negative output signal NOS is output as the output signal OS, the second additional transistor TRA2 and the fifth transistor TR5 can be turned on, the second control signal CS2 and the fourth control signal CS4 can be in the same phase, and a negative voltage with a magnitude greater than that of the fourth voltage level Lv4 can be output to the output terminal OUT. At this time, the positive output drive circuit 200 can be in a disabled state due to the turn-off of the first transistor TR1.

The above description is merely an example of the technical idea of the present embodiment, and those with ordinary knowledge in the technical field to which the present embodiment belongs may make various modifications and variations without departing from the essential characteristics of the present embodiment. Therefore, the present embodiments are not intended to limit the technical idea of the present embodiment, but rather to explain it, and the scope of the technical idea of the present embodiment is not limited by these embodiments. The scope of protection of this embodiment should be interpreted by the claims below, and all technical ideas within a scope equivalent thereto should be interpreted as being included in the scope of protection of this embodiment.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. An output drive circuit comprising:
a control signal generation circuit configured to receive a data signal as input, and output a first control signal and a second control signal;
a positive output drive circuit configured to receive the first control signal as input, and output a positive output signal;
a negative output drive circuit configured to receive the second control signal as input, and output a negative output signal;
a connection circuit connecting the positive output drive circuit and the negative output drive circuit; and
an output terminal connected to the connection circuit,
wherein when the data signal is at a first voltage level, the first control signal is at a second voltage level, and the second control signal is at the first voltage level,
when the data signal is at a third voltage level, the first control signal is at the first voltage level, and the second control signal is at a fourth voltage level,
when the data signal is at the first voltage level, the negative output signal at the fourth voltage level is output to the output terminal, and
when the data signal is at the third voltage level, the positive output signal at the second voltage level is output to the output terminal.

2. The output drive circuit of claim 1, wherein the connection circuit comprises:
a first transistor having one end connected to the positive output drive circuit and the other end connected to the output terminal; and
a second transistor having one end connected to the output terminal and the other end connected to the negative output drive circuit.

3. The output drive circuit of claim 1, wherein the first voltage level is greater than the fourth voltage level,
the third voltage level is greater than the first voltage level, and
the second voltage level is greater than the third voltage level.

4. The output drive circuit of claim 1, wherein the control signal generation circuit comprises:
a positive level shifter configured to receive the data signal as input, and output a first voltage signal;
a negative level shifter configured to receive the data signal as input, and output a second voltage signal; and
a pre-drive circuit configured to receive the first voltage signal and the second voltage signal as input, output the first control signal having the first voltage level to the second voltage level, and output the second control signal having the fourth voltage level to the first voltage level.

5. The output drive circuit of claim 1, further comprising:
a HiZ generation circuit controlled by a HiZ control signal and connected to the positive output drive circuit,
wherein when the HiZ control signal is at the second voltage level, the output terminal outputs one of the negative output signal and the positive output signal according to the data signal, and
when the HiZ control signal is at the first voltage level, the output terminal enters a high-impedance state.

6. The output drive circuit of claim 5, wherein the control signal generation circuit comprises:
a positive level shifter configured to receive the data signal as input and output a first voltage signal, and receive a first input signal as input and output a first input voltage signal;
a negative level shifter configured to receive the data signal as input and output a second voltage signal, and receive the first input signal as input and output a second input voltage signal; and
a pre-drive circuit configured to receive the first voltage signal, the second voltage signal, the first input voltage signal, and the second input voltage signal as input, and output the HiZ control signal, the first control signal, and the second control signal, and
wherein the pre-drive circuit:
outputs the first control signal having the first voltage level to the second voltage level, based on the first voltage signal,
outputs the second control signal having the fourth voltage level to the first voltage level, based on the second voltage signal, and
outputs the HiZ control signal having the first voltage level to the second voltage level, based on the first input voltage signal.

7. The output drive circuit of claim 5, wherein the HiZ generation circuit comprises a transistor having one end connected to the positive output drive circuit and the other end connected to a ground voltage and controlled by the HiZ control signal.

8. The output drive circuit of claim 1, wherein at a first node, the connection circuit and the positive output drive circuit are connected to each other,
at a second node, the connection circuit and the negative output drive circuit are connected to each other, and
the output drive circuit further comprising:
a first additional circuit connected to the first node and a power supply at the second voltage level; and
a second additional circuit connected to the second node and a power supply at the fourth voltage level.

9. The output drive circuit of claim 8, wherein the control signal generation circuit comprises:
a positive level shifter configured to receive the data signal as input and output a first voltage signal, and receive a second input signal as input and output a third voltage signal;
a negative level shifter configured to receive the data signal as input and output a second voltage signal, and receive the second input signal as input and output a fourth voltage signal; and
a pre-drive circuit configured to receive the first voltage signal, the second voltage signal, the third voltage signal, and the fourth voltage signal as input, and output the first control signal, the second control signal, the third control signal, and the fourth control signal, and
wherein the pre-drive circuit:
outputs the first control signal having the first voltage level to the second voltage level, based on the first voltage signal,
outputs the second control signal having the fourth voltage level to the first voltage level, based on the second voltage signal,
outputs the third control signal having the first voltage level to the second voltage level, based on the third voltage signal, and
outputs the fourth control signal having the fourth voltage level to the first voltage level, based on the fourth voltage signal.

10. The output drive circuit of claim 8, wherein the first additional circuit comprises a first additional transistor having one end connected to the power supply at the second voltage level and the other end connected to the first node, and
the second additional circuit comprises a second additional transistor having one end connected to the second node and the other end connected to the power supply at the fourth voltage level.

11. An output drive circuit comprising:
a control signal generation circuit configured to receive a data signal as input, and output a first control signal and a second control signal;
a positive output drive circuit configured to receive the first control signal as input, and output a positive output signal;
a negative output drive circuit configured to receive the second control signal as input, and output a negative output signal;
a connection circuit connecting the positive output drive circuit and the negative output drive circuit; and
an output terminal connected to the connection circuit,
wherein the connection circuit comprises:
a first transistor having one end connected to the positive output drive circuit and the other end connected to the output terminal; and
a second transistor having one end connected to the output terminal and the other end connected to the negative output drive circuit, and
wherein the positive output drive circuit comprises:
a third transistor having one end connected to a positive voltage and the other end connected to a first node, and controlled by the first control signal; and
a fourth transistor having one end connected to the first node and the other end connected to a ground voltage, and controlled by the first control signal.

12. The output drive circuit of claim 11, wherein the negative output drive circuit comprises:
a fifth transistor having one end connected to a second node and the other end connected to a negative voltage, and controlled by the second control signal; and
a sixth transistor having one end connected to the second node and the other end connected to the ground voltage, and controlled by the second control signal.

13. The output drive circuit of claim 11, wherein when the data signal is at a first voltage level, the first control signal is at a second voltage level, and the second control signal is at the first voltage level,
when the data signal is at a third voltage level, the first control signal is at the first voltage level, and the second control signal is at a fourth voltage level,
when the data signal is at the first voltage level, the negative output signal at the fourth voltage level is output to the output terminal, and
when the data signal is at the third voltage level, the positive output signal at the second voltage level is output to the output terminal.

14. The output drive circuit of claim 13, wherein the control signal generation circuit comprises:
a positive level shifter configured to receive the data signal as input, and output a first voltage signal;
a negative level shifter configured to receive the data signal as input, and output a second voltage signal; and
a pre-drive circuit configured to receive the first voltage signal and the second voltage signal as input, output the first control signal having the first voltage level to the second voltage level, and output the second control signal having the fourth voltage level to the first voltage level.

15. The output drive circuit of claim 11, further comprising:
a HiZ generation circuit controlled by a HiZ control signal and connected to the positive output drive circuit,
wherein when the HiZ control signal is at the second voltage level, the output terminal outputs one of the negative output signal and the positive output signal according to the data signal, and
when the HiZ control signal is at the first voltage level, the output terminal enters a high-impedance state.

16. The output drive circuit of claim 15, wherein the HiZ generation circuit comprises a transistor having one end connected to the positive output drive circuit and the other end connected to the ground voltage and controlled by the HiZ control signal.

17. The output drive circuit of claim 11, wherein at the first node, the connection circuit and the positive output drive circuit are connected to each other,
at a second node, the connection circuit and the negative output drive circuit are connected to each other, and
the output drive circuit further comprising:
a first additional circuit connected to the first node and a power supply at the second voltage level; and
a second additional circuit connected to the second node and a power supply at the fourth voltage level.

18. The output drive circuit of claim 17, wherein the first additional circuit comprises a first additional transistor having one end connected to the power supply at the second voltage level and the other end connected to the first node, and
the second additional circuit comprises a second additional transistor having one end connected to the second node and the other end connected to the power supply at the fourth voltage level.

19. An output drive circuit comprising:
a control signal generation circuit configured to receive a data signal as input, and output a first control signal and a second control signal;
a positive output drive circuit configured to receive the first control signal as input, and output a positive output signal;
a negative output drive circuit configured to receive the second control signal as input, and output a negative output signal;
a connection circuit connecting the positive output drive circuit and the negative output drive circuit;
an output terminal connected to the connection circuit; and
a HiZ generation circuit controlled by a HiZ control signal and connected to the positive output drive circuit,
wherein when the data signal is at a first voltage level, the first control signal is at a second voltage level, and the second control signal is at the first voltage level,
when the data signal is at a third voltage level, the first control signal is at the first voltage level, and the second control signal is at a fourth voltage level,
when the data signal is at the first voltage level, the negative output signal at the fourth voltage level is output to the output terminal,
when the data signal is at the third voltage level, the positive output signal at the second voltage level is output to the output terminal,
when the HiZ control signal is at the second voltage level, the output terminal outputs one of the negative output signal and the positive output signal according to the data signal, and
when the HiZ control signal is at the first voltage level, the output terminal enters a high-impedance state.

20. An output drive circuit comprising:
a control signal generation circuit configured to receive a data signal as input, and output a first control signal and a second control signal;
a positive output drive circuit configured to receive the first control signal as input, and output a positive output signal;
a negative output drive circuit configured to receive the second control signal as input, and output a negative output signal;
a connection circuit connected to the positive output drive circuit via a first node and connected to the negative output drive circuit via a second node;
an output terminal connected to the connection circuit;
a first additional circuit connected to the first node and a power supply at a second voltage level; and
a second additional circuit connected to the second node and a power supply at a fourth voltage level,
wherein when the data signal is at a first voltage level, the first control signal is at the second voltage level, and the second control signal is at the first voltage level,
when the data signal is at a third voltage level, the first control signal is at the first voltage level, and the second control signal is at the fourth voltage level,
when the data signal is at the first voltage level, the negative output signal at the fourth voltage level is output to the output terminal, and
when the data signal is at the third voltage level, the positive output signal at the second voltage level is output to the output terminal.
